(19) United States
(12) Patent Application Publication
(10) Pub. No.: US 2026/0190723 A1
(43) Pub. Date: Jul. 2, 2026

(54) Display Device

(71) Applicant: LG Display Co., Ltd., Seoul (KR)

(72) Inventors: KwanSoo Kim, Seoul (KR); JongWoo Park, Goyang-si (KR)

(21) Appl. No.: 19/421,459

(22) Filed: Dec. 16, 2025

(30) Foreign Application Priority Data
Dec. 30, 2024 (KR) 10-2024-0200083

(51) Int. Cl. H10K 59/131; H10K 59/12; H10K 59/122

(52) U.S. Cl. CPC H10K 59/1315; H10K 59/1201; H10K 59/122

(57) ABSTRACT

A display device presented herein features a display panel with uniform luminance. The display device includes a substrate including an emission area and a non-emission area, a light emitting element disposed in the emission area on the substrate and including a first electrode, an organic layer, and a second electrode, an auxiliary wiring on the substrate and in the non-emission area, an auxiliary electrode on the auxiliary wiring and including a protrusion in at least a part of a side surface, a bank in a part of a top surface of the auxiliary electrode and including at least one hole in the non-emission area, a deposition prevention layer on the bank and the auxiliary electrode, and a connection pattern in contact with at least a part of each side surface of the second electrode and the protrusion, and the protrusion and the connection pattern overlap the hole of the bank.

### CROSS-REFERENCE TO RELATED APPLICATION

The present application claims the priority to Republic of Korea Patent Application No. 10-2024-0200083 filed on Dec. 30, 2024, which is incorporated herein by reference in its entirety.

### FIELD

The present disclosure relates to a display device, and more particularly, for example, without limitation, to an organic light emitting display device which reduces a resistance of a cathode electrode through an auxiliary wiring.

### BACKGROUND

The field of organic light emitting display devices that visually display electrical information signals has developed rapidly, and research for developing performances such as thinning, weight reduction, and low power consumption for various types of organic light emitting display devices continues.

An electroluminescent organic light-emitting display device represented by an organic light-emitting display device is a self-emitting organic light-emitting display device, and does not require a separate light source, and thus may be manufactured as a lightweight, thin display device. Further, the electroluminescent organic light emitting display device is advantageous not only in terms of power consumption due to low voltage driving, but also in terms of color implementation, a response speed, a viewing angle, and a contrast ratio (CR).

The organic light emitting display device is divided into a top emission type and a bottom emission type according to the transmission direction of light emitted through the organic light emitting element. The bottom emission type has a disadvantage in that the aperture ratio is lowered due to the circuit element because the circuit element is located between the emission layer and the image display surface, whereas the top emission type has an advantage in that the aperture ratio is improved because the circuit element is not located between the emission layer and the image display surface.

The description provided in the background section should not be assumed to be prior art merely because it is mentioned in or associated with the background section. The background section may include information that describes one or more embodiments of the subject technology.

### SUMMARY

The inventors of the present disclosure found that, in the top emission type organic light emitting display device, since light emitted from an organic emission layer of an organic light emitting element passes through a cathode electrode, the cathode electrode is formed using a transparent conductive material. As a result, there is a problem that the resistance of the cathode electrode increases.

An object to be achieved by the present disclosure is to provide a display device in which a second electrode of a light emitting element is connected to an auxiliary wiring line to reduce a resistance of the second electrode and have uniform luminance throughout a display panel.

An object to be achieved by the present disclosure is to provide a display device having a structure capable of connecting an auxiliary wiring and a second electrode in units of subpixels.

An object to be achieved by the present disclosure is to provide a display device having a structure in which an auxiliary wiring and a second electrode are easily connected.

Objects of the present disclosure are not limited to the above-mentioned objects, and other objects, which are not mentioned above, can be clearly understood by those skilled in the art from the following descriptions.

According to one or more embodiments of the present disclosure, a display device includes a substrate including an emission area and a non-emission area surrounding the emission area, a light emitting element disposed in the emission area on the substrate and including a first electrode, an organic layer, and a second electrode, an auxiliary wiring disposed on the substrate and disposed in the non-emission area, an auxiliary electrode disposed on the auxiliary wiring and including a protrusion in at least a part of a side surface, a bank disposed in a part of a top surface of the auxiliary electrode and including at least one hole in the non-emission area, a deposition prevention layer disposed on the bank and the auxiliary electrode, and a connection pattern in contact with at least a part of each of the second electrode and the side surface of the protrusion, and the protrusion and the connection pattern overlaps the hole of the bank.

Other detailed matters of the embodiments are included in the detailed description and the drawings.

According to one or more embodiments of the present disclosure, by using the deposition prevention layer disposed on the second electrode, it is possible to stably electrically connect the second electrode and the auxiliary wiring through process optimization.

According to one or more embodiments of the present disclosure, the second electrode of the light emitting element is connected to the auxiliary wiring, but the second electrode and the auxiliary wiring are connected in units of sub-pixels to expand the contact area of the second electrode and the auxiliary wiring, thereby providing a low-power display device with reduced contact resistance and current density.

The effects according to the present disclosure are not limited to the contents exemplified above, and more various effects are included in the present disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain the principle of the present disclosure. The above and other embodiments, features and other advantages of the present disclosure will be more clearly understood from the following detailed description taken in conjunction with the accompanying drawings, in which:

FIG. 1 is a schematic plan view of a display device according to one or more embodiments of the present disclosure.

FIG. 2 is a plan view illustrating signal lines and an auxiliary electrode disposed in the display device according to one or more embodiments of the present disclosure

FIG. 3 is a cross-sectional view taken along line A-B of FIG. 2.

FIG. 4 is an enlarged view of an area X of FIG. 3.

FIG. 5 is an enlarged view of an area Y of FIG. 3.

FIG. 6 is a view schematically illustrating a part of a process of forming a connection pattern of a display device according to one or more embodiments of the present disclosure.

FIG. 7 is a cross-sectional view illustrating a schematic structure of a display device according to one or more other embodiments of the present disclosure.

FIG. 8 is a plan view illustrating signal lines and an auxiliary electrode disposed in a display device according to one or more other embodiments of the present disclosure.

FIG. 9 is a cross-sectional view taken along the line C-D of FIG. 8.

FIG. 10 is a cross-sectional view taken along line E-F of FIG. 8.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes (e.g., sizes, lengths, widths, heights, thicknesses, locations, radii, diameters, and areas), ratios, angles, numbers, and the like illustrated in the accompanying drawings for describing the embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated. The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

In describing a time relationship, for example, when the temporal order is described as, for example, “after,” “subsequent,” “next,” and “before,” a case which is not continuous may be included unless a more limiting term, such as “just,” “immediate(ly),” or “direct(ly)” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

Although the terms “first”, “second”, “A,” “B,” “(a),” and “(b)” and the like are used for describing various components, these components are not confined by these terms. These terms are merely used for distinguishing one component from the other components. Therefore, a first component to be mentioned below may be a second component in a technical concept of the present disclosure. The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Like reference numerals generally denote like elements throughout the present disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, embodiments of the present disclosure will be described in detail with reference to accompanying drawings.

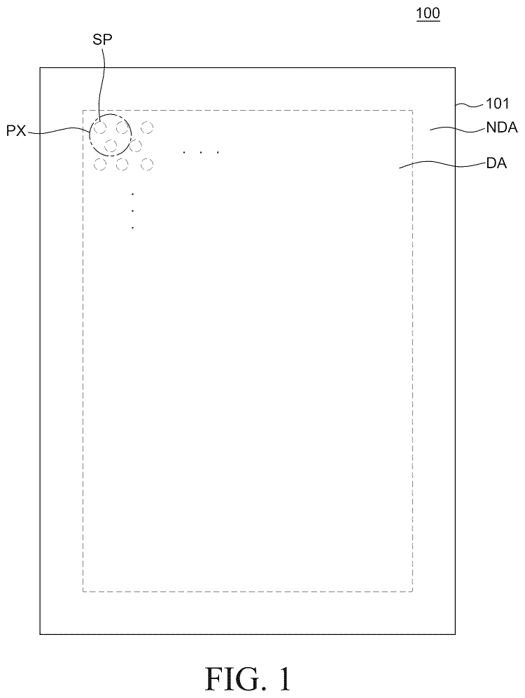

FIG. 1 is a schematic plan view of a display device according to one or more embodiments of the present disclosure.

Referring to FIG. 1, a display device 100 according to one or more embodiments of the present disclosure includes a display element displaying an image, a driving element driving the display element, and a display panel 101 provided with a signal line transmitting various signals to the display element and the driving element.

The display element may be differently defined depending on the type of the display panel 101.

In one or more embodiments of the present disclosure, it is described as an example that the display panel 101 is an organic light emitting display panel. In this case, the display element may be an organic light emitting element including an anode electrode, an organic light emitting layer, and a cathode.

As an example, the display device 100 according to one or more embodiments of the present disclosure may be an organic light emitting display device in which a light emitting element is implemented as an organic light emitting diode(OLED).

As another example, the display device 100 may be an inorganic light emitting display device in which the light emitting element is implemented as a light emitting element based on an inorganic material.

As another example, the display device 100 may be a quantum dot display device in which a light emitting element is implemented by a quantum dot which is a self-emitting semiconductor crystal.

Further, the display device 100 according to one or more embodiments of the present disclosure may be a flexible organic light emitting display device. However, embodiments of the present disclosure are not limited thereto. As an example, the display device 100 according to one or more embodiments of the present disclosure may be a rigid organic light emitting display device, without being limited thereto.

The display panel 101 may include a substrate, a plurality of insulating films on the substrate, a transistor layer, a light emitting element layer, and the like.

The display panel 101 may include a plurality of subpixels SP and various signal lines for driving the plurality of subpixels SP to display an image. The signal line may include a plurality of data lines, a plurality of gate lines, a plurality of power lines, and the like.

A plurality of data lines and a plurality of gate lines disposed in the display panel 101 may cross each other.

Each of the plurality of data lines may be disposed while extending in the first direction. Each of the plurality of gate lines may be disposed while extending in the second direction.

Here, the first direction may be a column direction, and the second direction may be a row direction. Alternatively, the first direction may be a row direction and the second direction may be a column direction. However, embodiments of the present disclosure are not limited thereto. As an example, the first direction or the second direction may be a diagonal direction between the column direction and the row direction, without being limited thereto.

As illustrated in FIG. 1, the display panel 101 includes a display area DA in which an image is displayed and a non-display area NDA in which an image is not displayed. The display area DA may be include the light emitting area and the non-light-emitting area (NEA).

In the display area DA, a plurality of pixels PX, a plurality of sub-pixels SP constituting the pixels PX, may be disposed. Each sub pixel in the display area DA may have a pixel circuit for driving the sub-pixel SP.

Each of the subpixels SP may include a transistor positioned on a transistor layer and a light emitting element positioned on a light emitting element layer. The transistor and the light emitting element may at least partly overlap each other.

The subpixel SP is a minimum unit constituting the display area DA, and a display element may be disposed in each of the plurality of subpixels SP.

The pixel circuit for driving the plurality of sub-pixels SP may be formed of a thin film transistor, a storage capacitor, a gate line, a data line, and the like, but not limited thereto.

The non-display area NDA may be bent, such that the non-display area NDA is not visible from a front surface or may be covered by a case (not shown), and referred to as a bezel area. As an example, the non-display area NDA may fully or partially surround the display area DA, without being limited thereto.

Various lines and circuits for driving the light emitting element of the display area DA may be disposed in the non-display area NDA.

For example, in the non-display area NDA, a link line which transmits signals to a plurality of sub-pixels and circuits of the display area DA, a gate-in-panel (GIP) line, or a driving IC such as a gate driver IC or a data driver IC may be disposed, but it is not limited thereto.

For example, the non-display area NDA may include a ground line which is disposed to surround the display area DA and applies a common voltage to the subpixel, without being limited thereto. For example, the ground line may be formed as one or two or more, and when two or more ground lines are formed, the ground line positioned closer to the display area DA may be referred to as an internal ground line.

In addition, although not illustrated, the display device 100 may include a touch sensing unit including a plurality of touch electrodes. A touch routing line for transmitting a touch signal may be disposed on the plurality of touch electrodes.

In addition, the display device 100 may further include various additional elements for generating various signals or for driving the pixels in the display area DA. The additional elements for driving the pixels may include an inverter circuit, a multiplexer, an electrostatic discharge (ESD) circuit, and the like.

Further, the display device 100 may also include an additional element associated with a function other than driving of the pixel PX.

For example, the display device 100 may further include additional elements that provide a touch sensing function, a user authentication function (e.g., fingerprint recognition), a multi-level pressure sensing function, a tactile feedback function, and the like. The above-mentioned additional elements may be located in an external circuit connected to the non-display area NDA and/or the connection interface.

Further, the display device 100 includes a display driving circuit for driving the display panel 101 and may include a data driving circuit, a gate driving circuit, and a display controller as the display driving circuit.

The data driving circuit is a circuit for driving a plurality of data lines and may output data signals to a plurality of data lines. The gate driving circuit is a circuit for driving a plurality of gate lines and may output gate signals to a plurality of gate lines.

The display controller is a device for controlling a data driving circuit and a gate driving circuit, and may control a driving timing for a plurality of data lines and a driving timing for a plurality of gate lines.

The display controller may supply a data driving control signal to the data driving circuit to control the data driving circuit, and may supply a gate driving control signal to the gate driving circuit to control the gate driving circuit.

The display controller may receive input image data from the host system and supply the image data to the data driving circuit based on the input image data.

The data driving circuit may supply data signals to a plurality of data lines according to driving timing control of the display controller. The data driving circuit may receive digital image data from the display controller, convert the received image data into analog data signals, and output the analog data signals to a plurality of data lines.

The gate driving circuit may supply gate signals to a plurality of gate lines according to timing control of the display controller. The gate driving circuit may be supplied with a first gate voltage corresponding to a turn-on level voltage and a second gate voltage corresponding to a turn-off level voltage together with various gate driving control signals to generate gate signals and supply the generated gate signals to a plurality of gate lines.

The gate driving circuit supplies a gate signal to the gate line according to the gate driving control signal supplied from the display controller. The gate driving circuit may be disposed on one side or both sides of the display panel 101 in a gate in panel (GIP) manner. However, embodiments of the present disclosure are not limited thereto. As an example, the gate driving circuit may be provided on a separate panel or film, and then connected to the display panel 101 using a tape automated bonding (TAB) method, a chip-on-glass (COG) method, a chip-on-panel (COP) method, or a chip-on-film (COF) method, etc., without being limited thereto.

The gate driving circuit sequentially outputs the gate signal to a plurality of gate lines under the control of the display controller. The gate driving circuit shifts the gate signal using a shift register to sequentially supply the signals to the gate lines.

The gate signal may include a scan signal and an emission control signal in the display device 100. The scan signal pulse is synchronized with the data voltage to select the subpixels SP of the line on which data is to be written. The emission control signal defines an emission time of each sub pixel SP.

As an example, at least one of the data driving circuit and the gate driving circuit may be disposed in the display area DA of the display panel 101, without being limited thereto.

For example, at least one of the data driving circuit and the gate driving circuit may be disposed so as not to overlap the sub pixels SP, or may be disposed so as to partially or entirely overlap the sub pixels SP, without being limited thereto.

Further, the display device 100 may further include a power supply circuit which supplies various types of power to the display driving circuit and/or the touch sensing circuit.

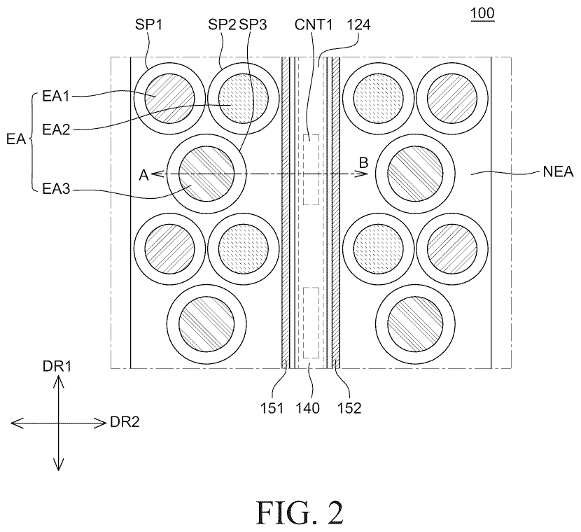

FIG. 2 is a plan view illustrating signal lines and an auxiliary electrode disposed in the display device according to one or more embodiments of the present disclosure.

In FIG. 2, some of a plurality of subpixels SP disposed in the display area DA of the display panel 101 of FIG. 1 are enlarged and illustrated.

Referring to FIG. 2, a plurality of sub-pixels SP may be disposed in the display area DA of the display panel 101.

The plurality of subpixels SP may include a first subpixel SP1, a second subpixel SP2, and a third subpixel SP3.

As an example, the first subpixel SP1 may be a red subpixel that emits red light, the second subpixel SP2 may be a green subpixel that emits green light, and the third subpixel SP3 may be a subpixel that emits blue light, without being limited thereto. As an example, the first subpixel SP1, the second subpixel SP2, and the third subpixel SP3, may emit light of the same color or different colors. As an example, the plurality of subpixels SP may further include at least one subpixel emitting light of a different color from the first subpixel SP1, the second subpixel SP2, and the third subpixel SP3. As an example, subpixels emitting light of other colors such as cyan, magenta, or yellow, etc. may be alternatively or additionally included.

However, the types of the plurality of subpixels SP included in the display device 100 of the present disclosure are not limited thereto.

For example, the plurality of subpixels SP may include a first subpixel SP1, a second subpixel SP2, a third subpixel SP3, and a fourth subpixel. Herein, the fourth subpixel may be a subpixel that emits white light.

Each sub pixel SP may include at least one emission area (or light-emitting area) EA.

For example, the first sub-pixel SP1 may include at least one first emission area EA1, the second sub-pixel SP2 may include at least one second emission area EA2, and the third sub-pixel SP3 may include at least one third emission area EA3. As an example, the number of emission areas in each sub-pixel may be the same as or different from each other.

Each of the first emission area EA1, the second emission area EA2, and the third emission area EA3 may have a circular shape in a plan view, but is not limited thereto.

For example, each of the first emission area EA1, the second emission area EA2, and the third emission area EA3 may have a polygonal shape, such as a rectangle, a hexagon, or an octagon, or various shapes, such as an oval shape.

Areas of at least two of the first emission area EA1, the second emission area EA2, and the third emission area EA3 may be different, but are not limited thereto.

In the display area DA of the display panel 101, a non-emission area (or non-light-emitting area) NEA surrounding the plurality of emission areas EA may be disposed.

A plurality of signal lines 140, 151, and 152, auxiliary wiring 124, and a contact area may be disposed in the non-emission area NEA. The auxiliary wiring 124 may be also called auxiliary line 124.

Specifically, the plurality of signal lines 140, 151, and 152 may include a first signal line 140, a second signal line 151, and a third signal line 152.

Here, the first signal line 140 may be a low-potential voltage supply line, and the second signal line 151 and the third signal line 152 may be data lines, but are not limited thereto.

A plurality of signal lines 140, 151, and 152 may extend in the first direction DR1 in the non-emission area NEA.

Although not illustrated in FIG. 2, a plurality of scan lines extending in a second direction DR2 which is a direction intersecting the first direction DR1 may be disposed in the non-emission area NEA of the display area DA.

The auxiliary line 124 may be disposed in the non-emission area NEA.

At least a portion of the auxiliary wiring 124 may be disposed to overlap the first signal line 140.

In addition, the auxiliary wiring 124 may be formed in a shape surrounding the plurality of emission areas EA, but is not limited thereto.

In addition, a first contact region CNT1 may be provided in a partial region of the auxiliary wiring 124.

In the first contact region CNT1, the auxiliary wiring 124 and the first signal line 140 may be electrically connected.

Further, an electrode (e.g., a cathode electrode) included in the light emitting element may be electrically connected to the auxiliary wiring 124.

The display device 100 according to one or more embodiments of the present disclosure may be a top emission type display device.

In the top emission method, a transparent cathode electrode for applying a common voltage to the emission layer of the light emitting element may be used. Since the transparent cathode electrode has such a high resistance value, the display device 100 according to one or more embodiments of the present disclosure may provide a uniform resistance of the cathode electrode over the entire display area DA through an electrical connection between the cathode electrode and the auxiliary wiring.

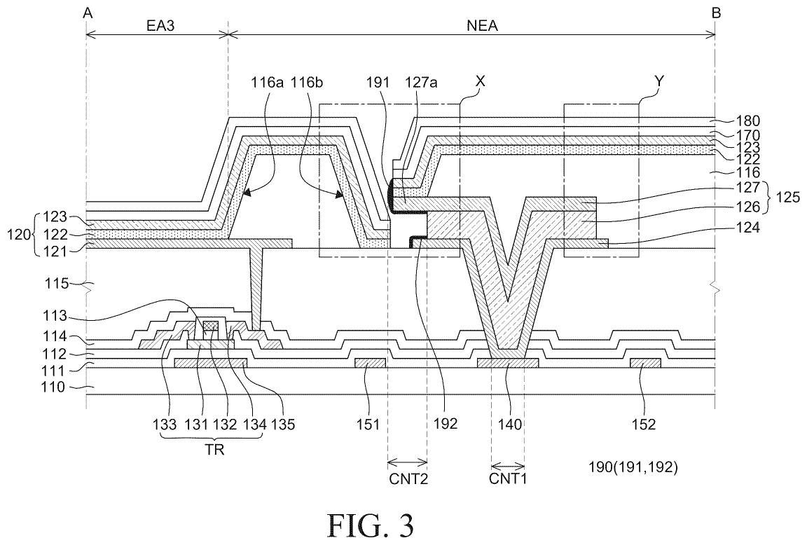

This will be specifically reviewed with reference to FIG. 3 as follows.

FIG. 3 is a cross-sectional view taken along line A-B of FIG. 2.

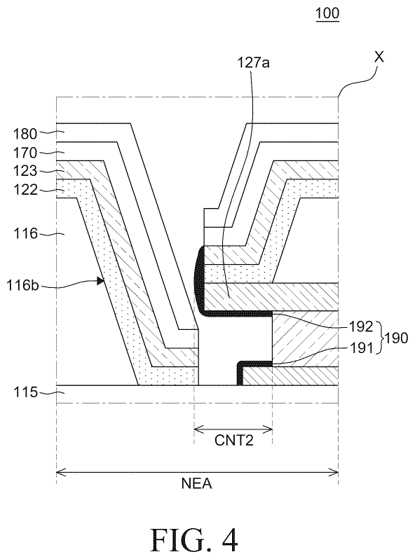

FIG. 4 is an enlarged view of an area X of FIG. 3.

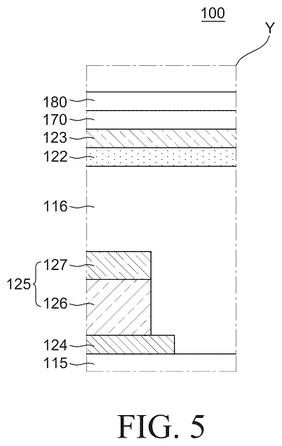

FIG. 5 is an enlarged view of an area Y of FIG. 3.

The X region of FIG. 4 is an enlarged view of one side of the auxiliary line 124 and an auxiliary electrode 125, and the Y region of FIG. 5 is an enlarged view of the other side of the auxiliary line 124 and the auxiliary electrode 125.

One side and the other side of the auxiliary line 124 and the auxiliary electrode 125 described through FIGS. 3 to 5 refer to side surfaces along a direction based on the second direction of FIG. 2. Here, the second direction refers to a direction crossing or perpendicular to the direction in which the first signal line 140 extends.

Referring to FIGS. 3 to 5, at least one transistor TR and a light-emitting element 120 may be disposed on the substrate 110 in the display area DA of the display device 100.

The transistor TR may include an active layer 131, a gate electrode 132, a source electrode 134, and a drain electrode 133.

The light-emitting element 120 may include a first electrode 121, an organic layer 122, and a second electrode 123.

Specifically, as an example, the light blocking layer 135 may be disposed on the substrate 110.

The light blocking layer 135 may be disposed below the active layer 131 of the transistor TR to serve as a light shield.

The light blocking layer 135 may be any one of magnesium (Mg), aluminum (Al), nickel (Ni), chromium (Cr), molybdenum (Mo), tungsten (W), gold (Au), titanium (Ti), nickel (Ni), neodymium (Nd), and copper (Cu), or an alloy of two or more, or may be a multilayer thereof, but is not limited thereto. For example, the light blocking layer 135 may be formed of an organic material. As an example, the light blocking layer 135 may be floated or may be supplied with a voltage, without being limited thereto. As an example, the light blocking layer 135 may be omitted depending on the design.

The buffer layer 111 may be disposed on the light blocking layer 135.

The buffer layer 111 may be configured by a single layer of silicon nitride (SiNx) or silicon oxide (SiOx), which is an inorganic material, or a multi-layer of silicon nitride (SiNx) or silicon oxide (SiOx), but is not limited thereto.

The active layer 131 of the transistor TR may be disposed on the buffer layer 111.

The active layer 131 may be formed of an oxide semiconductor, or may be formed of amorphous silicon (a-Si), polycrystalline silicon (poly-Si), or an organic semiconductor, but is not limited thereto.

A gate insulating film 113 may be disposed on the active layer 131.

The gate insulating film 113 may be configured as a single layer of silicon nitride (SiNx) or silicon oxide (SiOx), which is an inorganic material, or a multilayer of silicon nitride (SiNx) or silicon oxide (SiOx), but is not limited thereto.

The gate electrode 132 may be disposed on the gate insulating film 113.

The gate electrode 132 may be any one of magnesium (Mg), aluminum (Al), nickel (Ni), chromium (Cr), molybdenum (Mo), tungsten (W), gold (Au), titanium (Ti), nickel (Ni), neodymium (Nd), and copper (Cu), or an alloy of two or more, or a multilayer thereof, but is not limited thereto.

The active layer 131 may include a channel region overlapping the gate electrode 132, a first source connection region located at one side of the channel region, and a drain connection region located at the other side of the channel region.

The interlayer insulating layer 112 may be disposed on the substrate 110 on which the gate electrode 132 is disposed.

The interlayer insulating layer 112 may be configured by a single layer of silicon nitride (SiNx) or silicon oxide (SiOx), which is an inorganic material, or a multi-layer of silicon nitride (SiNx) or silicon oxide (SiOx), but is not limited thereto.

The source electrode 134 and the drain electrode 133 may be disposed on the interlayer insulating layer 112.

The source electrode 134 and the drain electrode 133 may be any one of magnesium (Mg), aluminum (Al), nickel (Ni), chromium (Cr), molybdenum (Mo), tungsten (W), gold (Au), titanium (Ti), nickel (Ni), neodymium (Nd), and copper (Cu), or an alloy of two or more, or a multilayer thereof, but are not limited thereto.

The source electrode 134 and the drain electrode 133 may be respectively connected to a source connection region and a drain connection region of the active layer 131 through a contact hole provided in the interlayer insulating layer 112.

A protection layer 114 may be disposed on the source electrode 134 and the drain electrode 133.

The protection layer 114 may be configured as a single layer of silicon nitride (SiNx) or silicon oxide (SiOx) which is an inorganic material, or a multi-layer of silicon nitride (SiNx) or silicon oxide (SiOx), but is not limited thereto.

The planarization layer 115 may be disposed on the protection layer 114.

The planarization layer 115 may include an organic material, and may serve to protect the transistor TR and planarize an upper surface.

The light-emitting element 120 including the first electrode 121, the organic layer 122, and the second electrode 123 may be disposed on the planarization layer 115.

The first electrode 121 may be an anode electrode of the light-emitting element 120, and the second electrode 123 may be a cathode electrode of the light-emitting element 120.

The display device 100 according to one or more embodiments of the present disclosure is a top emission type in which light emitted from the light-emitting element 120 is emitted to the upper portion of the substrate 110. As an example, the first electrode 121 may include a reflective electrode layer, without being limited thereto.

For example, the first electrode 121 may be a single layer including a reflective electrode layer, but is not limited thereto and may be configured by a multi-layer including a reflective electrode layer.

The reflective electrode layer of the first electrode 121 may be made of silver (Ag), aluminum (Al), gold (Au), molybdenum (Mo), tungsten (W), chromium (Cr), or an alloy thereof, without being limited thereto.

Further, when the first electrode 121 is formed of multiple layers, a transparent conductive layer disposed under the reflective electrode layer or above and below the reflective electrode layer may be further included, without being limited thereto.

The transparent conductive layer may include, for example, at least one of indium tin oxide (ITO), indium zinc oxide (IZO), or indium gallium zinc oxide (IGZO), but is not limited thereto.

The first electrode 121 may be in contact with the source electrode 134 of the transistor TR through a contact hole provided in the protection layer 114 and the planarization layer 115.

A bank 116 may be disposed on a part of the upper surface of the first electrode 121 and a part of the upper surface of the planarization layer 115.

The bank 116 may be made of an inorganic insulating material, such as silicon nitride (SiNx) or silicon oxide (SiOx), or an organic insulating material, such as benzocyclobutene-based resin, acrylic resin, or polyimide (PI), or imide-based resin, but is not limited thereto.

The bank 116 may be disposed to cover an edge of the first electrode 121.

The bank 116 may include a first bank hole 116a overlapping a part of an upper surface of the first electrode 121. The bank 116 is provided for separating the sub pixels from each other, in particular, the fist electrodes of adjacent sub pixels.

An area in which the first bank hole 116a is disposed may be an emission area EA of one subpixel SP. The first bank hole 116a is surrounded by the bank 116.

An area which does not overlap the first bank hole 116a overlapping a part of the upper surface of the first electrode 121 may be a non-emission area NEA.

The organic layer 122 of the light-emitting element 120 may be disposed on the substrate 110 on which the bank 116 is disposed.

The organic layer 122 includes a light-emitting layer and may be configured by a single layer or a multi-layer.

The second electrode 123 of the light-emitting element 120 may be disposed on the organic layer 122.

The second electrode 123 may be formed of a metal alloy such as MgAg, ytterbium (Yb) alloy, or a transparent conductive material such as indium tin oxide (ITO), indium zinc oxide (IZO), or may further include a metal doping layer, but is not limited thereto.

The organic layer 122 and the second electrode 123 may cover and/or overlap the bank 116.

In the display area DA of the display device 100, the first signal line 140, the second signal line 151, and the third signal line 152 may be disposed on the substrate 110.

Each of the first signal line 140, the second signal line 151, and the third signal line 152 may be disposed on the same layer as the light blocking layer 135, but is not limited thereto. The first signal line 140, the second signal line 151, and the third signal line 152 may be disposed on different layers from the light blocking layer 135. As an example, at least two or all of the first signal line 140, the second signal line 151, and the third signal line 152 may be disposed on different layers, without being limited thereto. Although it is illustrated that the first signal line 140 is disposed between the second signal line 151, and the third signal line 152, embodiments are not limited thereto. As an example, The first signal line 140 may be directly disposed on the substrate.

A buffer layer 111, an interlayer insulating layer 112, a protection layer 114, and a planarization layer 115 may be sequentially disposed on the first signal line 140, the second signal line 151, and the third signal line 152.

As an example, an auxiliary wiring 124 may be disposed on the planarization layer 115, without being limited thereto.

The auxiliary wiring 124 may be disposed on the same layer as the first electrode 121 of the light-emitting element 120, without being limited thereto.

As an example, the auxiliary wiring 124 is the same as and may include the same material as the structure of the first electrode 121 of the light-emitting element 120, without being limited thereto.

The auxiliary wiring 124 may be in contact with the first signal line 140 through contact holes provided in the buffer layer 111, the interlayer insulating layer 112, the protection layer 114, and the planarization layer 115.

However, the present disclosure is not limited thereto, and an auxiliary wiring connection electrode which electrically connects the auxiliary wiring 124 and the first signal line 140 may be further disposed between the auxiliary wiring 124 and the first signal line 140. The auxiliary wiring connection electrode may be disposed on the same layer as the gate electrode 132, or may be disposed on the same layer as the source electrode 134 and the drain electrode 133, without being limited thereto.

The auxiliary electrode 125 may be disposed on the auxiliary wiring 124.

As an example, the auxiliary electrode 125 may include a first auxiliary electrode 126 disposed on the auxiliary line 124 and a second auxiliary electrode 127 disposed on the first auxiliary electrode 126, without being limited thereto. As an example, the auxiliary electrode 125 may include one single electrode, or three or more electrodes stacking on each other, without being limited thereto.

Each of the first auxiliary electrode 126 and the second auxiliary electrode 127 may be any one of magnesium (Mg), aluminum (Al), nickel (Ni), chromium (Cr), molybdenum (Mo), tungsten (W), gold (Au), titanium (Ti), nickel (Ni), neodymium (Nd), and copper (Cu), or an alloy of two or more, or a multilayer thereof, but is not limited thereto. As an example, the first auxiliary electrode 126 and the second auxiliary electrode 127 may include the same material or different materials.

As an example, an area of the second auxiliary electrode 127 may be larger than an area of the first auxiliary electrode 126, without being limited thereto. As an example, the area of the second auxiliary electrode 127 may be smaller than or equal to the area of the first auxiliary electrode 126.

Accordingly, on a cross-section, one side of the second auxiliary electrode 127 may protrude from one side of the first auxiliary electrode 126.

Further, in cross section, the position of the other side of the second auxiliary electrode 127 may be the same as the position of the other side of the first auxiliary electrode 126, or the other side of the first auxiliary electrode 126 may protrude from the other side of the second auxiliary electrode 127.

Accordingly, the auxiliary electrode 125 including the first auxiliary electrode 126 and the second auxiliary electrode 127 may have an inverted taper shape at one side and a regular taper shape at the other side.

The auxiliary electrode 125 may be arranged groups of sub pixels and extend in a first direction parallel to the first signal line 140 and/or overlapping at least partly the first signal line 140. It may have extensions in the second direction, wherein the protrusion may extend in the second direction. The protrusion 127a may be a portion of the auxiliary electrode 125 being further extending than the lower part of the auxiliary electrode 125. Thus the end portion of the protrusion 127a may not overlap the auxiliary wiring below the auxiliary electrode 125.

The first auxiliary electrode 126 may be thicker than the second auxiliary electrode 127.

However, the present disclosure is not limited thereto, and the auxiliary electrode 125 may have an inverted taper shape at one side and a shape in which the side surface is aligned in one direction at the other side. Here, one direction may mean the same direction as a direction in which the buffer layer 111 is stacked on the substrate 110. As an example, the one side of the auxiliary electrode 125 may be one side facing the emission area, without being limited thereto. As an example, the one side of the auxiliary electrode 125 may be one side facing away from the emission area, without being limited thereto.

The bank 116 may not be disposed on the one side of the auxiliary electrode 125, and the bank 116 may be disposed on the other side of the auxiliary electrode 125. So, at one side of the auxiliary electrode 125 there is a portion of the bank being in contact with the auxiliary electrode 125 and at the other or opposing side of auxiliary electrode 125, there is no bank 116.

When the bank 116 includes an inorganic material, the bank 116 may be formed along the surface shape of the components disposed therebelow. In this case, if the other side of the auxiliary electrode 125 has an inverted taper shape, the bank 116 disposed on the other side of the auxiliary electrode 125 may be disposed along the inverted taper shape of the auxiliary electrode 125 as it is.

The organic layer 122 and the second electrode 123 may be disposed on the bank 116. Since the bank 116 disposed on the other side of the auxiliary electrode 125 and the other side of the auxiliary electrode 125 has an inversely tapered shape, the second electrode 123 may be disconnected in the area where the auxiliary electrode 125 and the bank 116 protrude.

In order to reduce or prevent the occurrence of such a defect, the shape of the other side of the auxiliary electrode 125 according to one or more embodiments of the present disclosure may have a shape aligned in one direction or a regular tapered shape.

After depositing the first auxiliary electrode material on the substrate 110 on which the auxiliary wiring 124 is disposed, the first auxiliary electrode material may be patterned through a dry etching process or the like to form the first auxiliary electrode 126. Thereafter, the second auxiliary electrode material is deposited on the substrate 110 on which the first auxiliary electrode 12 is disposed, and then the second auxiliary electrode material is patterned through a dry etching process or the like to form the second auxiliary electrode 127 having an area larger than the area of the first auxiliary electrode 126.

However, the process of forming the first auxiliary electrode 126 and the second auxiliary electrode 127 is not limited thereto.

For example, a first auxiliary electrode material may be deposited on the substrate 110 on which the auxiliary wiring 124 is disposed, and a second auxiliary electrode material may be formed on the first auxiliary electrode material.

In this case, the first auxiliary electrode material and the second auxiliary electrode material may be different. For example, the first auxiliary electrode material may include a material having an etch rate faster than that of the second auxiliary electrode material, without being limited thereto.

In the process of etching the first auxiliary electrode material and the second auxiliary electrode material, since the etching rate of the first auxiliary electrode material is faster than the etching rate of the second auxiliary electrode material, the amount of etching the first auxiliary electrode material may be larger than the amount of etching the second auxiliary electrode material. Accordingly, at least one side of the finally formed second auxiliary electrode 127 may be formed to include a protrusion 127a which is an area protruding from one side of the first auxiliary electrode 126.

Further, the auxiliary electrode 125 including the first auxiliary electrode 126 and the second auxiliary electrode 127 may have an inverted taper shape at one side and a regular taper shape at the other side. The photoresist thickness used in the etching process may vary for each area.

Specifically, a first photoresist may be formed on one side of the first auxiliary electrode material and the second auxiliary electrode material (a portion where the auxiliary electrode 125 has an inverted tapered shape), and a second photoresist may be formed on the other side of the first auxiliary electrode material and the second auxiliary electrode material (a portion where the auxiliary electrode 125 has a regular tapered shape).

Thereafter, the height of the first photoresist positioned at one side of the first auxiliary electrode material and the second auxiliary electrode material may be etched to be lower than the height of the second photoresist using a halftone mask. In this process, both the first auxiliary electrode material and the second auxiliary electrode material disposed in an area in which the first photoresist and the second photoresist are not formed may be removed. Thereafter, the first photoresist is removed to pattern one side of the first auxiliary electrode material and the second auxiliary electrode material to form the first auxiliary electrode 126 and the second auxiliary electrode 127 having an inverted taper structure.

In this process, the second photoresist having a height higher than that of the first photoresist remains on the other sides of the first auxiliary electrode material and the second auxiliary electrode material, so that the other sides of the first auxiliary electrode material and the second auxiliary electrode material may maintain a regular tapered shape without being etched.

However, the process of forming the first auxiliary electrode 126 and the second auxiliary electrode 127 is not limited thereto.

The auxiliary electrode 125 may include a protrusion 127a from which the second auxiliary electrode 127 protrudes compared to the first auxiliary electrode 126 at one side having an inverted tapered shape on a cross section. As an example, the protrusion 127a of the second auxiliary electrode 127 may be an area in which the second auxiliary electrode 127 does not overlap the first auxiliary electrode 126.

A bank 116 may be disposed on a part of the upper surface of the second auxiliary electrode 127.

The bank 116 may be disposed to expose a part of a top surface of the second auxiliary electrode 127, a part of a side surface of the second auxiliary electrode 127, and a part of a rear surface of the second auxiliary electrode 127 on one side of the auxiliary electrode 125 having an inverted taper shape.

At least some areas of the areas in which the second auxiliary electrode 127 does not overlap the bank 116 may not overlap the first auxiliary electrode 126.

Further, the bank 116 may be disposed to expose a part of the side surface of the first auxiliary electrode 126.

Specifically, the bank 116 may not overlap the side surface of the first auxiliary electrode 126 on one side of the auxiliary electrode 125 having an inverted tapered shape.

Further, the bank 116 may be disposed to expose a part of the top surface of the auxiliary line 124 and a part of the side surface of the auxiliary line 124. As an example, the bank 116 may be disposed to expose a part of an edge of the auxiliary wiring 124.

Specifically, at least a partial area of the auxiliary line 124 overlapping an area in which the second auxiliary electrode 127 does not overlap the bank 116 may not overlap the bank 116.

In addition, a part of the upper surface of the planarization layer 115 may be exposed in an area adjacent to the edge of the auxiliary wiring 124 that does not overlap the bank 116.

The bank 116 may include a second bank hole 116b in the non-emission area NEA. The second bank hole 116b may overlap a part of the top surface of the planarization layer 115, a part of the protrusion 127a of the second auxiliary electrode 125, and a part of the auxiliary line 124 overlapping the protrusion 127a of the second auxiliary electrode 125.

The organic layer 122 of the light-emitting element 120 may be disposed on the substrate 110 on which the bank 116 is disposed. As an example, the organic layer 122 of the light-emitting element 120 may be disposed on the substrate 110 in the second bank hole 116b. As an example, the organic layer 122 of the light-emitting element 120 may be disposed on the substrate 110 in the second bank hole 116b to be spaced apart from the edge of the auxiliary wiring 124.

The organic layer 122 may be formed by evaporating a raw material and depositing it (e.g., evaporation), without being limited thereto.

The organic layer 122 may be disposed in the entire emission area EA and a part of the non-emission area NEA.

Specifically, in the non-emission area NEA, the organic layer 122 may be disposed to surround the upper surface and the side surface of the bank 116.

Further, in the non-emission area NEA, the organic layer 122 may be disposed on the top surface of the second auxiliary electrode 127 which does not overlap the bank 116.

The organic layer 122 may include an area that is not disposed in a part of the non-emission area NEA.

Specifically, the organic layer 122 may be disposed to expose a part of the side surface of the first auxiliary electrode 126 and a part of the side surface of the second auxiliary electrode 127.

The organic layer 122 may be disposed to expose a side surface of the second auxiliary electrode 127, a rear surface of the second auxiliary electrode 127, and a side surface of the first auxiliary electrode 126 on one side of the auxiliary electrode 125 having an inverted taper shape.

The organic layer 122 may be deposited by evaporating a raw material and thus has a low step coverage characteristic. The step coverage means that the film deposited by a predetermined deposition method is formed to continue without interruption even in the step region.

In the area in which the protrusion 127a of the second auxiliary electrode 127 is disposed, the protrusion 127a of the second auxiliary electrode 127 may serve as a covering film to reduce or prevent the organic layer 122 from being formed there below in the process of forming the organic layer 122. Accordingly, the organic layer 122 may not be deposited on the planarization layer 115 under the protrusion 127a in an area overlapping the protrusion 127a of the second auxiliary electrode 127.

Therefore, the organic layer 122 may not be disposed on at least a part of the side surface of the protrusion 127a of the second auxiliary electrode 127 and on the rear surface of the protrusion 127a of the second auxiliary electrode 127.

In addition, the organic layer 122 may not be disposed on the side surface of the first auxiliary electrode 126 covered by the protrusion 127a of the second auxiliary electrode 127.

In addition, the organic layer 122 may not be disposed on the upper surface and the side surface of the auxiliary line 124 overlapping the protrusion 127a of the second auxiliary electrode 127.

The organic layer 122 may be disposed in a partial region of the second bank hole 116b.

Specifically, the organic layer 122 may be disposed on the protrusion 127a of the second auxiliary electrode 127 in the second bank hole 116b.

Further, the organic layer 122 may be disposed on a part of the upper surface of the planarization layer 115 in the second bank hole 116b.

The organic layer 122 disposed on the top surface of the planarization layer 115 overlapping the second bank hole 116b may not overlap the protrusion 127a of the second auxiliary electrode 127. As an example, in the second bank hole 116b, the organic layer 122 may not be disposed on the planarization layer 115 in an area overlapping the protrusion 127a of the second auxiliary electrode 127.

The second electrode 123 may be disposed on the organic layer 122.

The second electrode 123 may include an area that is not disposed in a portion of the non-emission area NEA.

Specifically, the second electrode 123 may be disposed to expose a part of a side surface of the first auxiliary electrode 126 and a part of a side surface of the second auxiliary electrode 127.

The second electrode 123 may be disposed to expose a side surface of the second auxiliary electrode 127, a rear surface of the second auxiliary electrode 127, and a side surface of the first auxiliary electrode 126 on one side of the auxiliary electrode 125 having an inverted taper shape. Since the second electrode 123 is deposited by evaporating a raw material, the step coverage characteristic is low.

In the area in which the protrusion 127a of the second auxiliary electrode 127 is disposed, the protrusion 127a of the second auxiliary electrode 127 may serve as a covering film so that the second electrode 123 is not formed under the protrusion 127a of the second auxiliary electrode 127 in the process of forming the second electrode 123. Accordingly, the second electrode 123 may not be deposited under the protrusion 127a of the second auxiliary electrode 127 in an area

overlapping the protrusion 127a of the second auxiliary electrode 127.

The protrusion 127a may be arranged on a higher level than the second electrode of the adjacent subpixel and may have no contact to the layers of the adjacent subpixel. However, there will be the light emitting layer 122 and the second electrode 123 on top of auxiliary electrode 125, which are then both higher than the second electrode 123 of the adjacent subpixel and are not in contact due to the length of the protrusion 127a.

Therefore, the second electrode 123 may not be disposed on at least a portion of the side surface of the protrusion 127a of the second auxiliary electrode 127 and the rear surface of the protrusion 127a of the second auxiliary electrode 127.

In addition, the second electrode 123 may not be disposed on the side surface of the first auxiliary electrode 126 covered by the protrusion 127a of the second auxiliary electrode 127.

In addition, the second electrode 123 may not be disposed on the upper surface and the side surface of the auxiliary line 124 overlapping the protrusion 127a of the second auxiliary electrode 127.

The second electrode 123 may be disposed in a partial area of the second bank hole 116b.

Specifically, the second electrode 123 may be disposed on the organic layer 122 in the second bank hole 116b. As an example, the second electrode 123 may be disposed on the top surface of the protrusion 127a of the second auxiliary electrode 127 in the second bank hole 116b.

Further, the second electrode 123 may be disposed in a part of the upper surface of the planarization layer 115 in the second bank hole 116b.

The second electrode 123 disposed on the top surface of the planarization layer 115 overlapping the second bank hole 116b may not overlap the protrusion 127a of the second auxiliary electrode 127. As an example, in the second bank hole 116b, the second electrode 123 may not be disposed under the protrusion 127a of the second auxiliary electrode 127 in an area overlapping the protrusion 127a of the second auxiliary electrode 127. As an example, the second electrode 123 may have the same size as the organic layer 122, without being limited thereto. As an example, the end of the second electrode 123 may be aligned with the end of the organic layer 122 on the upper surface of the planarization layer 115 in the second bank hole 116b, without being limited thereto. As an example, the end of the second electrode 123 may be aligned with the end of the organic layer 122 on the upper surface of the protrusion 127a of the second auxiliary electrode 127 in the second bank hole 116b, without being limited thereto.

As an example, a deposition prevention layer 170 may be disposed on the second electrode 123.

The deposition prevention layer 170 may be disposed in a partial area of the emission area EA and the non-emission area NEA.

The deposition prevention layer 170 may include an area not disposed in a portion of the non-emission area NEA.

Specifically, the deposition prevention layer 170 may be disposed to expose a part of a side surface of the first auxiliary electrode 126 and a part of a side surface of the second auxiliary electrode 127.

The deposition prevention layer 170 may be disposed to expose a side surface of the second auxiliary electrode 127, a rear surface of the second auxiliary electrode 127, and a side surface of the first auxiliary electrode 126 on one side of the auxiliary electrode 125 having an inverted taper shape.

In addition, the deposition prevention layer 170 may not be disposed on the side surface of the first auxiliary electrode 126 covered by the protrusion 127a of the second auxiliary electrode 127.

In addition, the deposition prevention layer 170 may not be disposed on the upper surface and the side surface of the auxiliary line 124 overlapping the protrusion 127a of the second auxiliary electrode 127.

A part of the protrusion 127a of the second auxiliary electrode 127 may overlap a part of the upper surface of the planarization layer 115 exposed by the auxiliary wiring 124 and the bank 116.

The deposition prevention layer 170 may be disposed in a partial area of the second bank hole 116b.

Specifically, the deposition prevention layer 170 may be disposed on the organic layer 122 in the second bank hole 116b. As an example, the deposition prevention layer 170 may be disposed on the top surface of the protrusion 127a of the second auxiliary electrode 127 in the second bank hole 116b.

In addition, the deposition prevention layer 170 may be disposed on a part of the upper surface of the planarization layer 115 in the second bank hole 116b.

The deposition prevention layer 170 disposed on the top surface of the planarization layer 115 overlapping the second bank hole 116b may not overlap the protrusion 127a of the second auxiliary electrode 127. As an example, in the second bank hole 116b, the deposition prevention layer 170 may not be disposed under the protrusion 127a of the second auxiliary electrode 127 in an area overlapping the protrusion 127a of the second auxiliary electrode 127.

As an example, the connection pattern 190 may be disposed in a part of the area overlapping the second bank hole 116b. The connection pattern 190 may serve to electrically connect the second electrode 123 and the auxiliary wiring 124.

The connection pattern 190 may be in contact with the second electrode 123 in a second contact region CNT2 and may be in contact with the auxiliary electrode 125. The second contact region CNT2 may be between the emission area EA and the first contact region CNT1.

Specifically, the connection pattern 190 may include a first connection pattern 191 and a second connection pattern 192.

The first connection pattern 191 and the second connection pattern 192 may be disposed to be spaced apart from each other. However, the present disclosure is not limited thereto, and the first connection pattern 191 and the second connection pattern 192 may have an integral shape. Alternatively, the connection pattern 190 may have a structure including only the first connection pattern 191.

The structure and shape of the connection pattern 190 may be changed according to the position of the protrusion 127a of the second auxiliary electrode 127.

For example, when the area of the protrusion 127a of the second auxiliary electrode 127 increases, the first connection pattern 191 may not be disposed on the auxiliary line 124. Further, as an area of the protrusion 127a of the second auxiliary electrode 127 decreases, a separation distance between the first connection pattern 191 and the second connection pattern 192 may decrease.

The first connection pattern 191 may be disposed on a side surface of the second electrode 123 and a side surface of the organic layer 122 in the second bank hole 116b.

In addition, the first connection pattern 191 may be disposed on a side surface of the protrusion 127a of the second auxiliary electrode 127 and at least a part of a rear surface of the protrusion 127a of the second auxiliary electrode 127 in the second bank hole 116b.

In addition, as an example, the first connection pattern 191 may be disposed on at least a portion of the side surface of the first auxiliary electrode 126 disposed below the protrusion 127a of the second auxiliary electrode 127, without being limited thereto. As an example, the first connection pattern 191 may be not disposed on the side surface of the first auxiliary electrode 126 disposed below the protrusion 127a, without being limited thereto.

As described above, the first connection pattern 191 is in contact with each of the second electrode 123 and the second auxiliary electrode 127 to electrically connect the second electrode 123 and the second auxiliary electrode 127. Further, the second auxiliary electrode 127 and the first auxiliary electrode 126 are in contact with each other, and the first auxiliary electrode 126 and the auxiliary line 124 are in contact with each other. As a result, the second electrode 123 and the auxiliary line 124 may be electrically connected by the first connection pattern 191.

The second connection pattern 192 may be disposed on a part of the upper surface and a part of the side surface of the auxiliary wiring 124. Specifically, the second connection pattern 192 may be disposed on a top surface and a side surface of the auxiliary line 124 which does not overlap the first auxiliary electrode 126.

The second electrode 123 may be an electrode which applies a common voltage to the organic layer 122 of the light-emitting element 120. In the top emission type display device 100, it is desirable to increase the transmittance of the second electrode 123 in order to increase the luminous efficiency.

In order to secure a high transmittance of the second electrode 123, a method of reducing the thickness of the second electrode 123 may be used, but there is a problem in that the resistance of the second electrode 123 increases.

In this case, as the luminance of the center portion of the display panel 101 decreases, a luminance imbalance phenomenon of the display panel 101 occurs, and when the size of the display panel 101 increases, the luminance imbalance phenomenon may be further increased.

In the display device 100 according to one or more embodiments of the present disclosure, the second electrode 123 and the auxiliary wiring 124 are electrically connected to provide a uniform resistance of the second electrode 123 over the entire display area DA and make the luminance of the entire display panel 101 uniform.

In addition, when the protrusion 127a of the auxiliary electrode 125 is disposed for each sub pixel of the display device 100, the second electrode 123 and the auxiliary line 124 may be electrically connected in units of sub pixels, so that the resistance of the second electrode 123 may be reduced, thereby improving the IR drop and luminance irregularity phenomenon. Embodiments are not limited thereto. As an example, the protrusion 127a of the auxiliary electrode 125 may be disposed for each of some of the sub pixels of the display device 100, without being limited thereto.

As an example, the some sub pixels may be widely distributed over the entire display area DA, without being limited thereto.

In particular, at least one side of the auxiliary electrode 125 is formed in an inversely tapered shape and the second auxiliary electrode 127 includes the protrusion 127a so that the organic layer 122 may not be disposed in some areas of the auxiliary electrode 125 and the auxiliary line 124 due to the role of the covering film of the protrusion 127a.

Therefore, the connection pattern 190 is in contact with each of the second electrode 123 and an area of the auxiliary electrode 125 in which the organic layer 122 is not disposed so that the second electrode 123 may be electrically connected to the auxiliary line 124.

The second contact area CNT2, which is an area in which the connection pattern 190 is in contact with each of the second electrode 123 and the protrusions 127a of the second auxiliary electrode 127, may be located between the first signal line 140 and the second signal line 151.

However, the present disclosure is not limited thereto. As an example, a part of the second contact area CNT2 may be located between the first signal line 140 and the second signal line 151, and the remaining part of the second contact area CNT2 may overlap the first signal line 140. As an example, the second contact area CNT2 may be located between the first signal line 140 and the third signal line 152, without being limited thereto.

A capping layer 180 may be disposed on the deposition prevention layer 170.

The capping layer 180 may be a single layer including an organic material or an inorganic material. However, the present disclosure is not limited thereto, and the capping layer 180 may be formed of a multilayer including an organic material or an inorganic material.

The capping layer 180 may be disposed in the emission area NEA and the non-emission area NEA to be spaced apart from the second electrode 123 by the deposition prevention layer 170.

When the capping layer 180 is disposed to be in contact with the second electrode 123, an exposed area of the second electrode 123 and the auxiliary electrode 125 may not exist. In this case, since the connection pattern 190 cannot be in contact with the second electrode 123 and the auxiliary electrode 125, it is difficult for the second electrode 123 to be electrically connected to the auxiliary electrode 125 and the auxiliary line 124.

In the display device 100 according to one or more embodiments of the present disclosure, the deposition prevention layer 170 is disposed between the capping layer 180 and the second electrode 123 to reduce or prevent the surfaces of the second electrode 123 and the auxiliary electrode 125 from being surrounded by the capping layer 180.

In addition, the deposition prevention layer 170 may serve to allow the connection pattern 190 to be in direct contact with the side surface of the second electrode 123 and a part of the auxiliary electrode 125.

Meanwhile, FIGS. 4 and 5 illustrate a structure in which the capping layer 180 is disposed on the deposition prevention layer 170. However, the structure of the display device 100 according to one or more embodiments of the present disclosure is not limited thereto. For example, the capping layer 180 may include the deposition prevention layer 170. As an example, the capping layer 180 may include a material having a repulsive force against metal, and the deposition prevention layer 170 may be omitted. As an example, the deposition prevention layer 170 may include a material having a repulsive force against metal, without being limited thereto.

In this way, by using the deposition prevention layer 170 disposed on the second electrode 123, the second electrode 123 and the auxiliary wiring 124 may be stably electrically connected through process optimization.

In addition, the second electrode 123 of the light-emitting element 120 is connected to the auxiliary line 124, but the second electrode 123 and the auxiliary line 124 are connected in units of the subpixel SP, such that the contact area between the second electrode 123 and the auxiliary line 124 may be extended, thereby providing the low-power display device 100 with reduced contact resistance and current density.

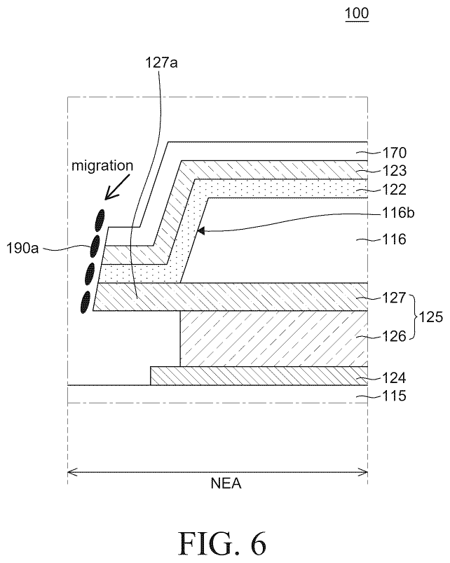

This will be reviewed in detail with reference to FIG. 6.

FIG. 6 is a view schematically illustrating a part of a process of forming a connection pattern of a display device according to one or more embodiments of the present disclosure. Referring to FIG. 6, a connection pattern material 190a may be formed on the substrate 110 on which the deposition prevention layer 170 is disposed.

As an example, the connection pattern material 190a may include a conductive material (e.g., a metal material), without being limited thereto.

For example, the connection pattern material 190a may be any one of magnesium (Mg), aluminum (Al), nickel (Ni), chromium (Cr), molybdenum (Mo), tungsten (W), gold (Au), titanium (Ti), nickel (Ni), neodymium (Nd), and copper (Cu), or an alloy of two or more. However, the connection pattern material 190a is not limited thereto.

As an example, the deposition prevention layer 170 may include an organic material, without being limited thereto. For example, the deposition prevention layer 170 may include an organic material including fluorine (F), without being limited thereto.

The deposition prevention layer 170 may have a repulsive force against the metal material. Accordingly, when the metal material is formed on the surface of the deposition prevention layer 170, a phenomenon in which the metal material is pushed due to the repulsive force may occur.

Accordingly, when the connection pattern material 190a including a metal material is formed on the deposition prevention layer 170, the connection pattern material is pushed out by the deposition prevention layer 170 due to the repulsive force.

Therefore, the connection pattern material 190a formed on the deposition prevention layer 170 may be pushed out of the deposition prevention layer 170 to be formed on each of a side surface of the second electrode 123, a side surface of the organic layer 122, and a side surface of the protrusion 127a of the second auxiliary electrode 127 disposed below the deposition prevention layer 170.

The connection pattern material 190a formed on the side surface of the second electrode 123, the side surface of the organic layer 122, and the side surface of the protrusion 127a of the second auxiliary electrode 127 may become the first connection pattern 191 shown in FIGS. 3 and 4, or may be included in a part of the first connection pattern 191.

In addition, as the amount of the connection pattern material 190a pushed by the deposition prevention layer 170 increases, the area in which the first connection pattern 191 is disposed may increase. For example, the first connection pattern 191 may be disposed not only on the side surface of the second electrode 123, the side surface of the organic layer 122, and the side surface of the protrusion 127a of the second auxiliary electrode 127, but also on at least a part of the rear surface of the protrusion 127a of the second auxiliary electrode 127 and one side surface of the first auxiliary electrode 126.

In addition, the connection pattern material 190a may be pushed by the deposition prevention layer 170 to be disposed on a part of the upper surface and a part of the side surface of the auxiliary wiring 124. The connection pattern material 190a may be the second connection pattern 192 illustrated in FIGS. 3 and 4.

In this way, the process may be optimized by simplifying the process of forming the connection pattern 190 electrically connecting the second electrode 123 and the auxiliary wiring 124 using the repulsive force of the deposition prevention layer 170 against the metal material.

Further, the second electrode 123 and the second auxiliary electrode 127 are electrically connected through the connection pattern 190 so that the second electrode 123 and the auxiliary line 124 are electrically connected to each other. Therefore, there is an effect of solving the luminance imbalance problem of the display panel 101 and having a high luminance characteristic on the front surface of the display panel 101.

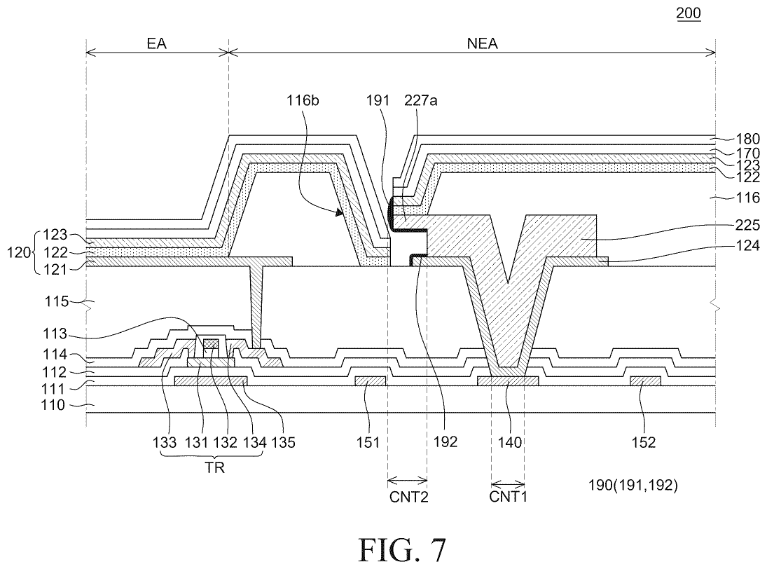

FIG. 7 is a cross-sectional view illustrating a schematic structure of a display device according to one or more other embodiments of the present disclosure. The only difference between a display device 200 of FIG. 7 and the display device 100 of FIG. 3 is a structure of an auxiliary electrode 225, but other components are substantially the same, so that a redundant description will be omitted or briefly given.

Referring to FIG. 7, the auxiliary electrode 225 disposed on the auxiliary line 124 may be formed of a single layer.

In this case, one side of the auxiliary electrode 225 may have an inverted taper shape. Further, the other side of the auxiliary electrode 225 may have a shape in which side surfaces are aligned in one direction or a regular tapered shape.

A protrusion 227a may be disposed on a part of one side of the auxiliary electrode 225.

The upper surface of the protrusion 227a may be in contact with the organic layer 122.

At least one second contact area CNT2 may be disposed in a part of the non-emission area NEA.

At least a portion of the second contact region CNT2 may overlap a portion of the region in which the auxiliary electrode 225 is disposed.

In the second contact area CNT2, the first connection pattern 191 may be in contact with the side surface of the second electrode 123, the side surface of the organic layer 122, and the side surface of the protrusion 227a of the auxiliary electrode 225. As such, the second electrode 123 may be electrically connected to the auxiliary electrode 225 which is in contact with the auxiliary line 124 through the first connection pattern 191.

Further, in the second contact area CNT2, the first connection pattern 191 may be disposed on at least a part of the rear surface of the protrusion 227a of the auxiliary electrode 225. However, the position of the first connection pattern 191 is not limited thereto.

Further, in the second contact area CNT2, the second connection pattern 192 may be disposed on the upper surface and the side surface of the auxiliary line 124.

A bank 116 may be disposed on the top surface and the side surface of the remaining auxiliary electrode 225 except for the second contact region CNT2 and the protrusion 227a of the auxiliary electrode 225.

At least one side of the auxiliary electrode 225 is formed in an inversely tapered shape and the auxiliary electrode 225 includes the protrusion 227a so that the organic layer 122 may not be disposed in a partial area of the auxiliary electrode 225 and the auxiliary wiring 124 due to the role of the covering film of the protrusion 227a.

Therefore, the connection pattern 190 is in contact with each of the second electrode 123 and an area of the auxiliary electrode 225 in which the organic layer 122 is not disposed so that the second electrode 123 may be electrically connected to the auxiliary line 124.

In addition, by electrically connecting the second electrode 123 and the auxiliary electrode 225 through the connection pattern 190 and electrically connecting the second electrode 123 and the auxiliary line 124, there is an effect of solving the luminance imbalance problem of the display panel 101 and having a high luminance characteristic on the front surface of the display panel 101.

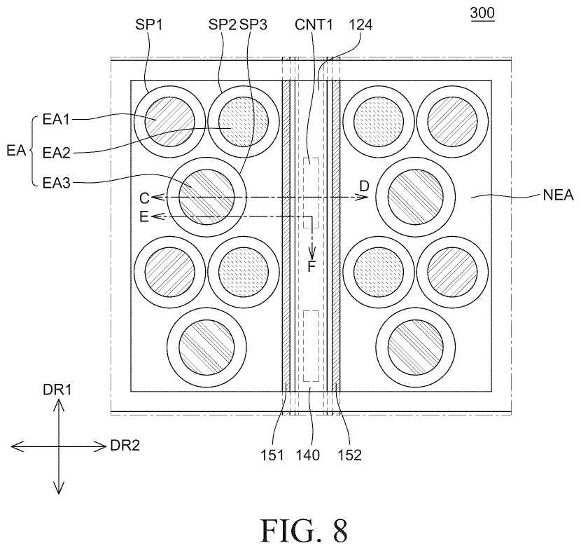

FIG. 8 is a plan view illustrating signal lines and an auxiliary electrode disposed in a display device according to one or more other embodiments of the present disclosure.

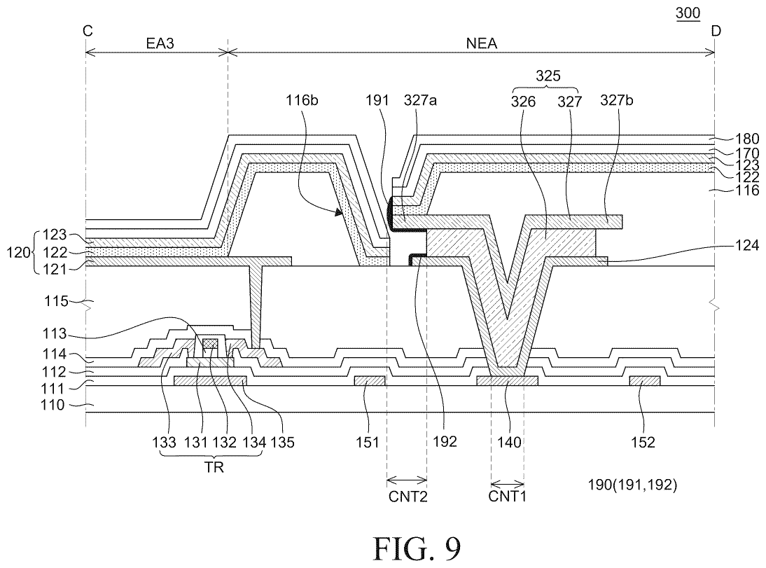

FIG. 9 is a cross-sectional view taken along the line C-D of FIG. 8.

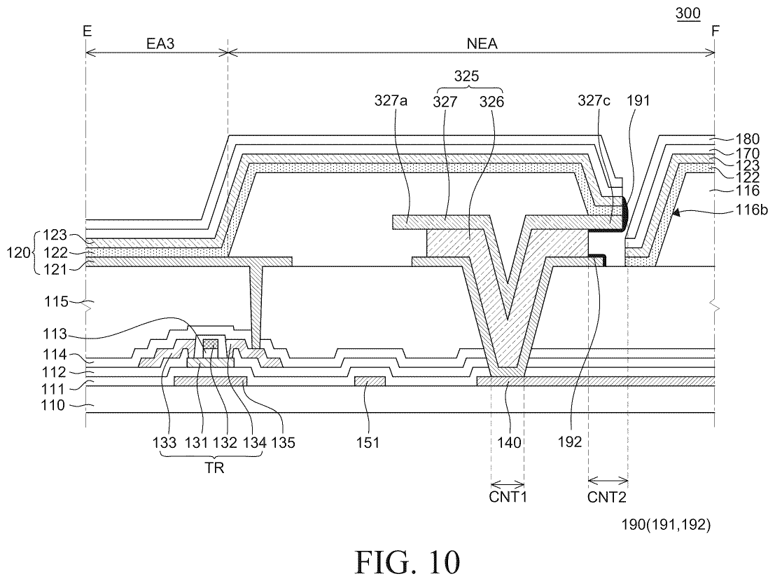

FIG. 10 is a cross-sectional view taken along line E-F of FIG. 8.

The only difference between a display device 300 of FIGS. 8 to 10 and the display device 100 of FIG. 3 is a structure of an auxiliary electrode 325, but other components are substantially the same, so that a redundant description will be omitted or briefly given.

Referring to FIGS. 8 to 10, the auxiliary electrode 325 may include a first auxiliary electrode 326 disposed on the auxiliary line 124 and a second auxiliary electrode 327 disposed on the first auxiliary electrode 326.

One side and the other side of the auxiliary electrode 325 may have an inverted taper shape. As an example, one side of the auxiliary electrode 325 facing the emission area EA3 and the other side of the auxiliary electrode 325 facing away from the emission area EA3 may have an inverted taper shape.

Specifically, the second auxiliary electrode 327 may include a first protrusion 327a disposed on one side and a second protrusion 327b disposed on the other side.

One side and the other side of the auxiliary electrode 325 described in FIGS. 8 to 10 refer to side surfaces along a direction based on the second direction of FIG. 8. Here, the second direction refers to a direction crossing or perpendicular to the direction in which the first signal line 140 extends.

Each of the first protrusion 327a and the second protrusion 327b may be an area that does not overlap the first auxiliary electrode 326.

A portion of each of the first protrusion 327a and the second protrusion 327b may overlap a portion of the auxiliary line 124, without being limited thereto.

Meanwhile, FIGS. 8 and 9 illustrate a structure in which the first protrusion 327a of the second auxiliary electrode 327 disposed on one side of the auxiliary electrode 325 is in contact with the first connection pattern 191, and the second protrusion 327b of the second auxiliary electrode 327 disposed on the other side of the auxiliary electrode 325 is not in contact with the first connection pattern 191, but is not limited thereto.

For example, the first connection pattern 191 may have a structure in contact with the second protrusion 327b of the second auxiliary electrode 327.

As an example, the second contact region CNT2 may be disposed on the other side of the auxiliary electrode 325.

Further, referring to FIGS. 8 and 10, as an example, side surfaces of the auxiliary electrode 325 may be formed in an inversely tapered shape in the remaining area except for one side and the other side.

For example, a side surface of the auxiliary electrode 325 in the direction in which the first signal line 140 of FIG. 8 extends, that is, the first direction DR2 may also be formed in an inversely tapered shape.

When the side surface of the auxiliary electrode 325 has an inversely tapered shape with respect to the direction in which the first signal line 140 extends, the second auxiliary electrode 327 of the auxiliary electrode 325 may include a third protrusion 327c on a cross-section.

In this case, as illustrated in FIG. 10, the second contact region CNT2 may overlap the first signal line 140.

In this way, the second auxiliary electrode 327 of the auxiliary electrode 325 is provided with protrusions (for example, the first protrusion 327a, the second protrusion 327b, and the third protrusion 327c) in various directions, so that the second contact area CNT2 may be freely designed.

Meanwhile, the first protrusion 327a, the second protrusion 327b, and the third protrusion 327c of the second auxiliary electrode 327 may be integrally formed on a plane or may be disposed to be spaced apart from each other.

As described above, each of the first protrusion 327a, the second protrusion 327b, and the third protrusion 327c of the second auxiliary electrode 327 is disposed in various directions so that the connection pattern 190 may be in contact with each of the second electrode 123 and the surface of the auxiliary electrode 325 on which the organic layer 122 is not disposed. Therefore, the second electrode 123 may be electrically connected to the auxiliary wiring 124.

Further, by electrically connecting the second electrode 123 and the auxiliary electrode 325 through the connection pattern 190 and electrically connecting the second electrode 123 and the auxiliary line 124, there is an effect of solving the luminance imbalance problem of the display panel 101 and having a high luminance characteristic on the front surface of the display panel 101.

Further, when the first protrusion 327a, the second protrusion 327b, and the third protrusion 327c of the second auxiliary electrode 327 are disposed for each sub pixel of the display device 100, the second electrode 123 may be electrically connected to the auxiliary line 124 in units of sub pixels. Therefore, the resistance of the second electrode 123 may be reduced and the IR drop and luminance irregularity phenomenon may be improved.

Further, by using the deposition prevention layer 170 disposed on the second electrode 123, the second electrode 123 and the auxiliary wiring 124 may be stably electrically connected through process optimization.

In addition, the second electrode 123 of the light-emitting element 120 is connected to the auxiliary line 124, but the second electrode 123 and the auxiliary line 124 are connected in units of the subpixel SP, such that the contact area between the second electrode 123 and the auxiliary line 124 may be extended, thereby providing the low-power display device 300 with reduced contact resistance and current density. So the several the second electrodes 123 of several sub pixels are connected to the auxiliary line 124 via the connection pattern 190.

According to one or more embodiments of the present disclosure, a display device includes a substrate including an emission area and a non-emission area surrounding the emission area, a light emitting element disposed in the emission area on the substrate and including a first electrode, an organic layer, and a second electrode, an auxiliary wiring disposed on the substrate and disposed in the non-emission area, an auxiliary electrode disposed on the auxiliary wiring and including a protrusion in at least a part of a side surface, a bank disposed in a part of a top surface of the auxiliary electrode and including at least one hole in the non-emission area, a deposition prevention layer disposed on the bank and the auxiliary electrode, and a connection pattern in contact with at least a part of each of the second electrode and the side surface of the protrusion, and the protrusion and the connection pattern overlaps the hole of the bank.

According to one or more embodiments of the present disclosure, in the non-emission area, at least a part of the organic layer may be disposed between the bank and the deposition prevention layer, in the non-emission area, at least a part of the second electrode may be disposed between the organic layer and the deposition prevention layer, and in the top surface of the protrusion, the organic layer, the second electrode, and the deposition prevention layer may be disposed.

According to one or more embodiments of the present disclosure, a part of the protrusion may overlap a part of the auxiliary wiring.

A planarization layer disposed between the substrate and the auxiliary wiring may be further included, and a part of the protrusion may overlap a part of an upper surface of the planarization layer exposed by the auxiliary wiring and the bank.

The auxiliary electrode may include a first auxiliary electrode disposed on the auxiliary wiring and a second auxiliary electrode disposed on the first auxiliary electrode.

According to one or more embodiments of the present disclosure, the area of the second auxiliary electrode may be larger than the area of the first auxiliary electrode.

According to one or more embodiments of the present disclosure, the protrusion may be disposed on at least one end of the second auxiliary electrode.

According to one or more embodiments of the present disclosure, the first auxiliary electrode may include a material having an etching speed higher than that of the second auxiliary electrode.

According to one or more embodiments of the present disclosure, the connection pattern may include a first connection pattern and a second connection pattern, the first connection pattern may be in contact with at least one side of the second electrode, at least one side of the organic layer and at least one side of the protrusion, at least a part of the rear surface of the protrusion, and the second connection pattern may be in contact with a part of the upper surface and a part of the side surface of the auxiliary wiring.

Each of the first connection pattern and the second connection pattern may be in contact with a portion of at least one side surface of the first auxiliary electrode.

According to one or more embodiments of the present disclosure, the side surface of the auxiliary electrode on which the protrusion is disposed may have an inverted taper shape on a cross-section.

The protrusion is disposed on one side of the auxiliary electrode and the other side of the auxiliary electrode on a cross-section may be aligned in one direction or may have a regular tapered shape.

According to one or more embodiments of the present disclosure, the protrusion may be disposed on one side and the other side of the auxiliary electrode on a cross-section.

According to one or more embodiments of the present disclosure, the bank may cover one of the protrusions disposed on one side and the other side of the auxiliary electrode.

The display device may further comprise a first signal line disposed on the substrate and a second signal line spaced apart from the first signal line, wherein at least a part of the connection pattern may be disposed between the first signal line and the second signal line.

According to one or more embodiments of the present disclosure, the auxiliary wiring may be electrically connected to the first signal line.

Each of the first signal line and the second signal line may extend in a first direction, and the protrusion may protrude in a second direction intersecting the first direction.

Each of the first signal line and the second signal line may extend in a first direction, and the protrusion may protrude in the first direction.

According to one or more embodiments of the present disclosure, at least a portion of the protrusion may overlap the first signal line.

The display device may further comprise a capping layer disposed on the deposition prevention layer, wherein the capping layer may be spaced apart from the second electrode in the emission area and the non-emission area.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate comprising a light-emitting area and a non-light-emitting area surrounding the light-emitting area;
a light-emitting element disposed in the light-emitting area on the substrate, the light-emitting element including a first electrode, an organic layer, and a second electrode;
an auxiliary wiring disposed on the substrate and disposed in the non-light-emitting area;
an auxiliary electrode disposed on the auxiliary wiring, the auxiliary electrode including a protrusion in at least a part of a side surface of the auxiliary electrode; and
a connection pattern,
wherein the organic layer and the second electrode are further disposed over the auxiliary electrode, and
wherein the connection pattern is in contact with at least a part of each of a side surface of the second electrode disposed over the auxiliary electrode and a side surface of the protrusion.

2. The display device according to claim 1, further comprising:
a bank disposed in a part of a top surface of the auxiliary electrode, the bank including at least one hole in the non-light-emitting area,
wherein the protrusion and the connection pattern overlap a hole of the at least one hole in the bank.

3. The display device according to claim 2, wherein, in the at least one hole in the bank, the organic layer is in contact with the auxiliary electrode and is interposed between the second electrode and the auxiliary electrode, and
wherein the connection pattern is further in contact with a side surface of the organic layer disposed on the auxiliary electrode.

4. The display device according to claim 2, wherein the organic layer and the second electrode disposed over the auxiliary electrode are spaced apart from the organic layer and the second electrode disposed in the light-emitting area in the at least one hole in the bank.

5. The display device according to claim 2, wherein the protrusion protrudes from an upper part of the side surface of the auxiliary electrode such that a lower surface of the protrusion is exposed.

6. The display device according to claim 2, further comprising:
a deposition prevention layer disposed on the bank and the auxiliary electrode.

7. The display device according to claim 6, wherein at least a part of the organic layer in the non-light-emitting area is disposed between the bank and the deposition prevention layer,
wherein at least a part of the second electrode in the non-light-emitting area is disposed between the organic layer and the deposition prevention layer, and
wherein the organic layer, the second electrode, and the deposition prevention layer are disposed on a top surface of the protrusion in the at least one hole in the bank.

8. The display device according to claim 1, wherein a part of the protrusion overlaps a part of the auxiliary wiring.

9. The display device of claim 2, further comprising:
a planarization layer disposed between the substrate and the auxiliary wiring,
wherein a part of the protrusion overlaps a part of an upper surface of the planarization layer exposed by the auxiliary wiring and the bank.

10. The display device according to claim 1, wherein the auxiliary electrode includes a first auxiliary electrode disposed on the auxiliary wiring and a second auxiliary electrode disposed on the first auxiliary electrode.

11. The display device according to claim 10, wherein an area of the second auxiliary electrode is larger than an area of the first auxiliary electrode.

12. The display device according to claim 10, wherein the protrusion is disposed at at least one end of the second auxiliary electrode.

13. The display device according to claim 10, wherein the first auxiliary electrode includes a material having an etching speed higher than that of the second auxiliary electrode.

14. The display device according to claim 1, wherein the connection pattern includes a first connection pattern and a second connection pattern,
wherein the first connection pattern is in contact with a side surface of the second electrode disposed over the auxiliary electrode, a side surface of the organic layer disposed over the auxiliary electrode, a side surface of the protrusion, and at least a part of a rear surface of the protrusion, and
wherein the second connection pattern is in contact with a part of a top surface of the auxiliary wiring and a part of a side surface of the auxiliary wiring.

15. The display device according to claim 14, wherein at least one of the first connection pattern and the second connection pattern is in contact with a part of a side surface of the auxiliary electrode.

16. The display device according to claim 14, wherein the first connection pattern and the second connection pattern are disposed to be spaced apart from each other, or to contact each other.

17. The display device according to claim 1, wherein a side surface of the auxiliary electrode on which the protrusion is disposed has an inverted taper shape on a cross-section.

18. The display device according to claim 1, wherein the protrusion is disposed on a first side of the auxiliary electrode, and
wherein a second side of the auxiliary electrode on a cross-section is aligned in a direction perpendicular to a top surface of the substrate or has a regular tapered shape.

19. The display device according to claim 2, wherein the protrusion is disposed on a first side of the auxiliary electrode and a second side of the auxiliary electrode on a cross-section.

20. The display device according to claim 19, wherein the bank covers one portion of the protrusion disposed on a first side of the auxiliary electrode and a second side of the auxiliary electrode.

21. The display device according to claim 1, further comprising:
a first signal line disposed on the substrate; and
a second signal line spaced apart from the first signal line,
wherein at least a part of the connection pattern is disposed between the first signal line and the second signal line.

22. The display device of claim 21, wherein the auxiliary wiring is electrically connected to the first signal line.

23. The display device of claim 21, wherein each of the first signal line and the second signal line extends in a first direction, and
wherein the protrusion protrudes in a second direction intersecting the first direction.

24. The display device according to claim 21, wherein each of the first signal line and the second signal line extends in a first direction, and
wherein the protrusion protrudes in the first direction.

25. The display device according to claim 24, wherein at least a part of the protrusion overlaps the first signal line.

26. The display device according to claim 6, further comprising:
a capping layer disposed on the deposition prevention layer,
wherein the capping layer is spaced apart from the second electrode in the light-emitting area and the non-light-emitting area.

27. The display device according to claim 1, wherein the connection pattern is provided in units of sub pixels.

28. The display device according to claim 6, wherein the deposition prevention layer includes a material having a repulsive force against metal.

29. The display device according to claim 1, further comprising:
a first signal line disposed on the substrate and extending in a first direction,
wherein the auxiliary wiring is electrically connected to the first signal line,
wherein the protrusion protrudes in the first direction and a second direction intersecting the first direction, and
wherein protrusions protruding in the first direction and protrusions protruding in the second direction are integrally formed on a plane or are disposed to be spaced apart from each other.
